(19) United States
(12) Patent Application Publication
(10) Pub. No.: US 2024/0062998 A1
(43) Pub. Date: Feb. 22, 2024

(54) SUBSTRATE PROCESSING METHOD AND SUBSTRATE PROCESSING APPARATUS

(71) Applicant: PSK INC., Gyeonggi-do (KR)

(72) Inventors: Jin Woo PARK, Gyeonggi-do (KR); Hyeong Shin CHO, Gyeonggi-do (KR)

(21) Appl. No.: 18/268,198

(22) PCT Filed: Dec. 9, 2021
(86) PCT No.: PCT/KR2021/018679

§ 371 Date: Jun. 16, 2023

(30) Foreign Application Priority Data
Dec. 18, 2020 (KR) 10-2020-0178152

(51) Int. Cl. H01J 37/32

(52) U.S. Cl. CPC H01J 37/32743; H01J 37/32788; H01J 37/32633; H01J 37/32816; H01J 37/3244; H01J 2237/336; H01J 2237/332

(57) ABSTRACT

Disclosed is a method of processing a substrate. The method may include: a substrate loading operation of loading a substrate into a treating space of a chamber; a film removal operation of removing a film provided on the substrate; a protective film formation operation of forming a protective film containing oxygen on the substrate; and a substrate unloading operation of unloading the substrate from the treating space.

### TECHNICAL FIELD

The present invention relates to a substrate processing method and a substrate processing apparatus.

### BACKGROUND ART

Plasma refers to an ionized gas state formed of ions, radicals, electrons, and the like, and is generated by a very high temperature, strong electric fields, or RF electromagnetic fields. A semiconductor device manufacturing process includes an ashing or etching process that uses plasma to remove a film on a substrate. The ashing or etching process is performed by ion and radical particles contained in the plasma colliding or reacting with a film on the substrate.

A device that processes a substrate by using plasma may be utilized to remove a film on the substrate (for example, a hard mask formed on the substrate, or a photoresist film formed on the substrate). After the film on the substrate is removed by using the plasma, the substrate is transferred to a liquid treatment chamber to remove any residual process byproducts on the substrate. In the liquid treatment chamber, a chemical solution is supplied to the substrate to remove any process byproducts that remain on the substrate.

In recent years, semiconductor device manufacturing processes have become increasingly complex, requiring precise processing of substrates. When a chemical solution is supplied to the substrate to remove process byproducts after the film on the substrate is removed as described above, the pattern formed on the substrate may be over-etched by the chemical solution. This over-etch phenomenon makes precise processing of the substrate difficult and makes it difficult to form efficient semiconductor device dimensions.

### DISCLOSURE

### Technical Problem

An object of the present invention is to provide a substrate processing method and a substrate processing apparatus which are capable of efficiently processing a substrate.

Another object of the present invention is to provide a substrate processing method and a substrate processing apparatus which are capable of minimizing a problem of over-etching a substrate when a chemical solution is supplied to the substrate to remove impurities remaining on the substrate after removing a film on the substrate.

The problem to be solved by the present invention is not limited to the above-mentioned problems, and the problems not mentioned will be clearly understood by those skilled in the art from the present specification and the accompanying drawings.

### Technical Solution

An exemplary embodiment of the present disclosure provides a method of processing a substrate, the method including: a substrate loading operation of loading a substrate into a treating space of a chamber; a film removal operation of removing a film provided on the substrate; a protective film formation operation of forming a protective film containing oxygen on the substrate; and a substrate unloading operation of unloading the substrate from the treating space.

According to the exemplary embodiment, the protective film formation operation may be performed after the film removal operation.

According to the exemplary embodiment, the protective film formation operation may be performed before the film removal operation.

According to the exemplary embodiment, the method may further include a liquid treatment operation of supplying a chemical solution to the substrate and removing impurities remaining on the substrate or the protective film after the substrate unloading operation.

According to the exemplary embodiment, the film removal operation may be performed by transferring plasma to the film.

According to the exemplary embodiment, in the film removal operation, a gap between a chuck supporting the substrate and a baffle disposed above the substrate may be a first gap, and a pressure in the treating space may be maintained at a first pressure, in the protective film formation operation, a gap between the chuck and the baffle may be a second gap greater than the first gap, and a pressure in the treating space may be maintained at a second pressure less than the first pressure, any one of the chuck and the baffle may be connected with a power unit that generates an electric field in the treating space, and the other of the chuck and the baffle may be grounded.

According to the exemplary embodiment, in the film removal operation, water, hydrogen, and inert gas may be supplied to the treating space, and in the protective film formation operation, water, hydrogen, and inert gas may be supplied to the treating space.

Another exemplary embodiment of the present disclosure provides an apparatus for processing a substrate, the apparatus including: a chamber having a treating space; a chuck for supporting a substrate in the treating space, and moving the substrate in upward and downward directions; a gas supply unit for supplying process gas to the treating space; a fluid supply unit for supplying a treatment fluid to the treating space; a baffle disposed above the substrate supported on the chuck and formed with a spray hole through which the process gas and/or the treatment fluid flows; an exhaust unit for exhausting the treating space; a power unit for generating an electric field in the treating space; and a controller, in which the controller controls at least one of the gas supply unit, the exhaust unit, the fluid supply unit, the chuck, and the power unit to remove a film provided on the substrate supported on the chuck, and to form a protective film containing oxygen on the substrate supported on the chuck.

According to the exemplary embodiment, the controller may control at least one of the gas supply unit, the exhaust unit, the fluid supply unit, the chuck, and the power unit to form the protective film, after the film is removed.

According to the exemplary embodiment, the controller may control at least one of the gas supply unit, the exhaust unit, the fluid supply unit, the chuck, and the power unit to form the protective film, before the film is removed.

According to the exemplary embodiment, the controller may control at least one of the chuck, the exhaust unit, the gas supply unit, and the fluid supply unit to maintain a gap between the chuck and the baffle at a first gap during removal of the film, and to maintain a pressure in the treating space at the first pressure, and the controller may control at least one of the chuck, the exhaust unit, the gas supply unit, and the fluid supply unit to maintain a gap between the chuck and the baffle at a second gap greater than the first gap, and to maintain a pressure in the treating space at a second pressure less than the first pressure, during the formation of the protective film

### Advantageous Effects

According to the exemplary embodiment of the present invention, it is possible to efficiently process a substrate.

According to the exemplary embodiment of the present invention, According to the exemplary embodiment of the present invention, it is possible to minimize the problem of over-etching the substrate by supplying a chemical solution into the substrate to remove any residual impurities on the substrate after removing the film on the substrate.

The effect of the present invention is not limited to the foregoing effects, and the not-mentioned effects will be clearly understood by those skilled in the art from the present specification and the accompanying drawings.

### DESCRIPTION OF DRAWINGS

FIG. 1 is a diagram illustrating a view of a substrate processed by a substrate processing apparatus according to an exemplary embodiment of the present invention.

FIGS. 2, 3, and 4 are diagrams schematically illustrating substrates that may be brought into a treating space of FIG. 1.

FIG. 5 is a flow chart illustrating a substrate processing method according to an exemplary embodiment of the present invention.

FIG. 6 is a diagram illustrating a substrate processing apparatus performing a film removal operation of FIG. 5.

FIG. 7 is a diagram illustrating a substrate after the film removal operation of FIG. 5 has been performed.

FIG. 8 is a diagram illustrating the substrate processing apparatus performing a protective film formation operation of FIG. 5.

FIG. 9 is a diagram illustrating a diagram illustrating the substrate on which the protective film formation operation of FIG. 5 has been performed.

FIG. 10 is a flow chart illustrating a substrate processing method according to another exemplary embodiment of the present invention.

### BEST MODE

Hereinafter, an exemplary embodiment of the present invention will be described more fully hereinafter with reference to the accompanying drawings, in which exemplary embodiments of the invention are illustrated. However, the present invention can be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” and variations, such as “includes” or “including” will be understood to imply the inclusion of stated elements but not the exclusion of any other elements. It will be appreciated that terms “including” and “having” are intended to designate the existence of characteristics, numbers, steps, operations, constituent elements, and components described in the specification or a combination thereof, and do not exclude a possibility of the existence or addition of one or more other characteristics, numbers, steps, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element can be directly coupled to or connected to the other constituent element, but intervening elements may also be present. In contrast, when one constituent element is “directly coupled to” or “directly connected to” another constituent element, it should be understood that there are no intervening element present. Other expressions describing the relationship between the constituent elements, such as “between ˜” and “just between ˜” or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

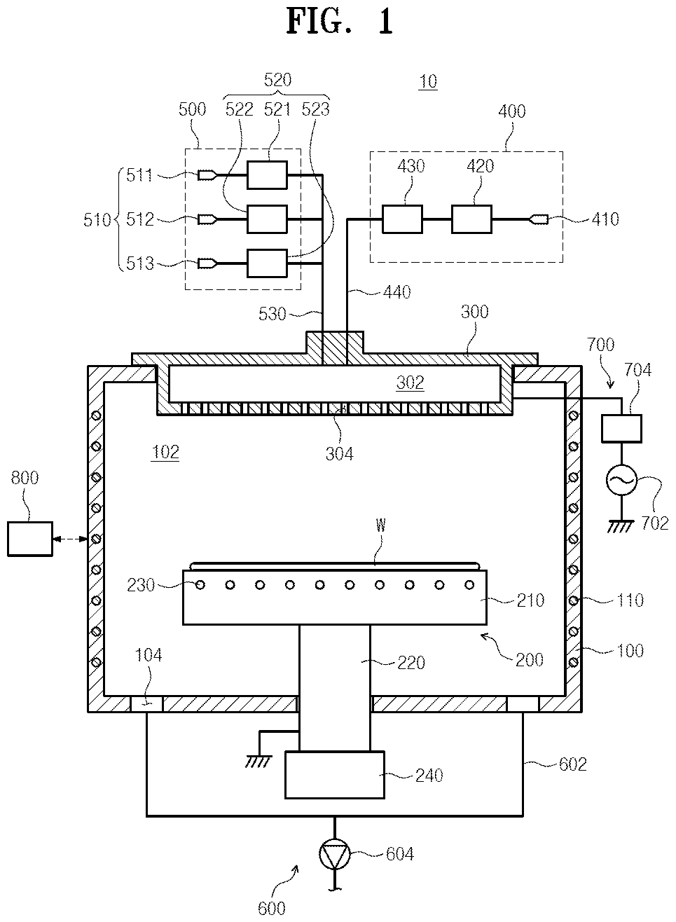

Exemplary embodiments of the present invention will be described in detail below with reference to FIGS. 1 to 9.

FIG. 1 is a drawing illustrating a view of a substrate processed by a substrate processing apparatus according to an exemplary embodiment of the present invention. Referring to FIG. 1, a substrate processing apparatus 10 according to an exemplary embodiment of the present invention may include a chamber 100, a chuck 200, a baffle 300, a fluid supply unit 400, a gas supply unit 500, an exhaust unit 600, a power unit 700, and a controller 800.

The chamber 100 may have a treating space 102. The chamber 100 may be grounded. The treating space 102 provided in the chamber 100 may be the space in which a thin film removal process of removing a hardmask formed on a substrate W is removed. An inlet (not illustrated) through which the substrate W is loaded into the treating space 102 or the substrate W is unloaded from the treating space 102 may be formed at one side of the chamber 100. The inlet may be selectively opened/closed by a door (not illustrated). Further, an exhaust hole 104 which is connected with the exhaust unit 600, which is to be described below, may be formed in a bottom surface of the chamber 100.

Further, a cooling member 110 may be provided to the chamber 100. The cooling member 110 may adjust a temperature of the chamber 100. The cooling member 110 may adjust a temperature of the treating space 102. The cooling member 110 may be a flow path connected with a cooling fluid supply source that supplies a cooling fluid. The cooling fluid supplied to the cooling member 110 may be cooling water or cooling gas. However, the present invention is not limited thereto, and the cooling member 110 may be variously modified into a publicly known member capable of transferring cooling heat to the chamber 100.

The chuck 200 may support the substrate W in the treating space 102. The chuck 200 may include a support plate 210, a support shaft 220, a lifting member 240, and a heating member 230. The support plate 210 may have a seating surface on which the substrate W is seated. The support plate 210 may have a substantially disk shape when viewed from above. Additionally, electrodes may be provided within the support plate 210. The electrodes provided within the support plate 210 may be grounded. Further, the support plate 210 may be supported by the support shaft 220.

The lifting member 240 may move the support shaft 220 in an upward or downward direction. The lifting member 240 may move the support shaft 220 in an up and down direction to change the height of the supported substrate W in the treating space 102.

Additionally, the heating member 230 may be provided within the support plate 210. The heating member 230 may be a heater. The heating member 230 may be a heater that is heated by receiving power from a heating source (not illustrated). The heating member 230 may receive power from a heating source to adjust the temperature of the substrate W supported on the support plate 210.

The baffle 300 may be disposed above the chuck 200. The baffle 300 may be disposed above the substrate W supported on the chuck 200. The baffle 300 may supply process gas and/or a treatment fluid to the treating space 102. The baffle 300 may be provided in a cylindrical shape having an inner space 302. Further, a spray hole 304, in which process gas and/or a treatment fluid flows, may be formed in a lower surface of the baffle 300. An injection port to which a fluid supply line 440 and a gas supply line 530, which will be described below, are connected may be formed on the upper portion of the baffle 300. The treatment fluid supplied by the fluid supply line 440 and the process gas supplied by the gas supply line 530 may flow into the inner space 302 through the injection port. The process gas and/or treatment fluid flowing into the inner space 302 may flow into the treating space 102 through the spray hole 304. Further, the lower surface of the baffle 300 may have a stepped shape in which the lower surface of the edge region is lower than the lower surface of the central region. Therefore, the baffle 300 may be installed while being inserted into an opening formed in the upper portion of the chamber 100. Further, the baffle 300 may be grounded.

The fluid supply unit 400 may supply the treatment fluid to the treating space 102. The treatment fluid supplied by the fluid supply unit 400 may include water (H₂O), alcohol, and the like. The alcohol may be methanol (MeOH) or ethanol (EtOH). Further, the fluid supply unit 400 may include a treatment fluid supply source 410, a vaporizer 420, a flow rate adjusting member 430, and the fluid supply line 440.

The treatment fluid supply source 410 may deliver the treatment fluid containing water (H₂O) to the vaporizer 420. Additionally, the treatment fluid supply source 410 may deliver the treatment fluid containing alcohol to the vaporizer 420. The alcohol may be methanol (MeOH) or ethanol (EtOH).

Further, the treatment fluid supply source 410 may deliver the liquid treatment fluid to the vaporizer 420. The vaporizer 420 may change the received treatment fluid to a vaporized state by a method of heating the received treatment fluid at a high temperature and the like. The high-temperature treatment fluid changed to the vaporized state in the vaporizer 420 may be delivered to the baffle 300 through the fluid supply line 440 connected with the baffle 300. Further, the treatment fluid delivered to the baffle 300 may be injected to the treating space 102 through the spray hole 304. Further, the flow rate adjusting member 430 may change a supply flow rate per unit time of the treatment fluid delivered to the baffle 300. The flow rate adjusting member 430 may be a regulator or a flow rate adjustment valve. However, the present invention is not limited thereto, and the flow rate adjusting member 430 may be variously modified to the publicly known device which is capable of changing a supply flow rate per unit time of the treatment fluid.

The gas supply unit 500 may supply process gas to the treating space 102. The process gas supplied to the treating space 102 by the gas supply unit 500 may include at least one of more of N₂, Ar, H₂, O₂, and O*.

The gas supply unit 500 may include a gas supply source 510, a flow rate control member 520, and a gas supply line 530.

The gas supply source 510 may supply process gas to the baffle 300 through the gas supply line 530. The process gas supplied to the baffle 300 may be supplied to the treating space 102 through the spray hole 304. The gas supply source 510 may include a first gas supply source 511, a second gas supply source 512, and a third gas supply source 513. The first gas supply source 511 may supply nitrogen (N₂) gas. The second gas supply source 512 may supply argon (Ar) gas. The third gas supply source 513 may supply hydrogen (H₂) gas. Further, a supply flow rate per unit time of the process gas supplied by the gas supply source 510 may be adjusted by the flow rate control member 520. For example, the flow rate control member 520 may include a first flow rate control member 521, a second flow rate control member 522, and a third flow rate control member 523. Further, a supply flow rate per unit time of the process gas supplied by the first gas supply source 511 may be adjusted by the first flow rate control member 521 installed in the gas supply line 530. Further, a supply flow rate per unit time of the process gas supplied by the second gas supply source 512 may be adjusted by the second flow rate control member 522 installed in the gas supply line 530. Further, a supply flow rate per unit time of the process gas supplied by the third gas supply source 513 may be adjusted by the third flow rate control member 523 installed in the gas supply line 530. The flow rate control member 520 may be a regulator or a flow rate adjusting valve. However, the present invention is not limited thereto, and the flow rate control member 520 may be variously modified to the publicly known device that adjusts a supply flow rate per unit time of the process gas.

The exhaust unit 600 may exhaust the treating space 102. The exhaust unit 600 may exhaust the treating space 102 at at least one of the following times: before the substrate W is processed, after the substrate W is processed, and while the substrate W is being processed. The exhaust unit 600 may exhaust the treating space 102 to discharge the process gas and the treatment fluid supplied to the treating space 102, and by-products (or impurities) that may be generated in the process of processing the substrate W to the outside of the treating space 102. The exhaust unit 600 may include an exhaust line 602 connected with the exhaust hole 104, and an exhaust member 604 providing the exhaust line 602 with reduced pressure. The exhaust member 604 may be a pump. However, the present invention is not limited thereto, and the exhaust member 604 may be variously modified to the publicly known device that provides the treating space 102 with reduced pressure and exhausts the treating space 102.

The power unit 700 may generate an electric field in the treating space 102. The power unit 700 may generate an electric field in the treating space 102 to generate plasma from the process gas or the treatment fluid supplied to the treating space 102. The power unit 700 may include a high-frequency power supply 702 and a matching unit 704. The high-frequency power supply 702 may be an RF power supply. The matching unit 704 may perform matching on the high-frequency power supply 702.

The controller 800 may control the substrate processing apparatus 10. The controller 800 may control the substrate processing apparatus 10 to perform a film removal process to remove a film on the substrate W, and a protective film formation process to form a protective film on the substrate W. For example, the controller 800 may control the substrate processing apparatus 10 to perform a substrate processing method described below. For example, the controller 800 may control at least one of the cooling member 110, the lifting member 240, the heating member 230, the heating power source that delivers power to the heating member 230, the fluid supply unit 400, the gas supply unit 500, the exhaust unit 600, and the power unit 700. Further, the controller 800 may include a process controller formed of a microprocessor (computer) that executes the control of the substrate processing apparatus 10, a user interface formed of a keyboard in which an operator performs a command input operation or the like in order to manage the substrate processing apparatus 10, a display for visualizing and displaying an operation situation of the substrate processing apparatus 10, and the like, and a storage unit storing a control program for executing the process executed in the substrate processing apparatus 10 under the control of the process controller or a program, that is, a treatment recipe, for executing the process in each component according to various data and processing conditions. Further, the user interface and the storage unit may be connected to the process controller. The treating recipe may be stored in a storage medium in the storage unit, and the storage medium may be a hard disk, and may also be a portable disk, such as a CD-ROM or a DVD, or a semiconductor memory, such as a flash memory.

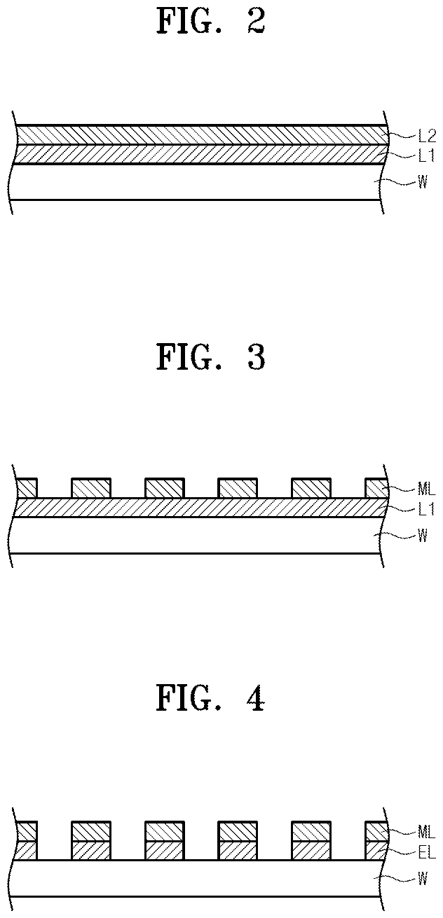

FIGS. 2, 3, and 4 are diagrams schematically illustrating substrates that may be brought into a treating space of FIG. 1. A film may be formed on the substrate W that may be brought into the treating space 102. For example, as illustrated in FIG. 2, an etching target layer L1 and a mask layer L2 may be formed on the substrate W. The substrate W illustrated in FIG. 2 is loaded into the treating space 102, and the substrate processing apparatus 10 may perform the substrate processing method described below. Furthermore, as illustrated in FIG. 3, the etching target layer L1 and a hard mask ML in which a portion of a mask layer L2 are removed to form a pattern may be formed on the substrate W. The substrate W illustrated in FIG. 3 is loaded into the treating space 102, and the substrate processing apparatus 10 may perform the substrate processing method described below. Furthermore, as illustrated in FIG. 4, an etched layer EL in which a portion of the etching target layer L1 is removed to form the same pattern as that of the hard mask ML, and the hard mask ML may be formed on the substrate W. The substrate W illustrated in FIG. 4 is loaded into the treating space 102, and the substrate processing apparatus 10 may perform the substrate processing method described below. Hereinafter, the present invention will be described based on the case where the substrate W illustrated in FIG. 4 is loaded into the treating space 102 and is processed by the substrate processing apparatus 10.

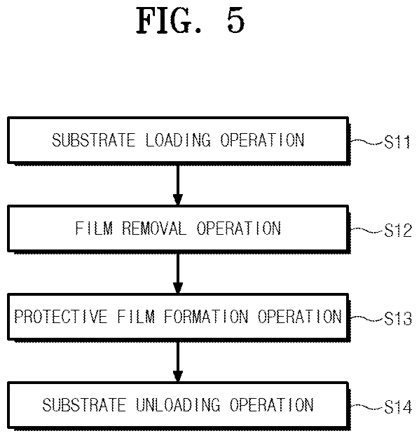

FIG. 5 is a flow chart illustrating the substrate processing method according to an exemplary embodiment of the present invention. Referring to FIG. 5, a substrate processing method according to one exemplary embodiment of the present invention may include a substrate loading operation S11, a film removal operation S12, a protective film formation operation S13, and a substrate unloading operation S14. The substrate loading operation S11, the film removal operation S12, the protective film formation operation S13, and the substrate unloading operation S14 may be sequentially performed.

In the substrate loading operation S11, the substrate W may be loaded in through a loading opening of the chamber 100. The loading of the substrate W may be performed by a hand of a transfer robot. In this case, a lift pin (not illustrated) provided in the chuck 200 may rise to support the substrate W seated on the hand, the hand may retract, and the lift pin may lower to make the substrate W be seated on the chuck 200.

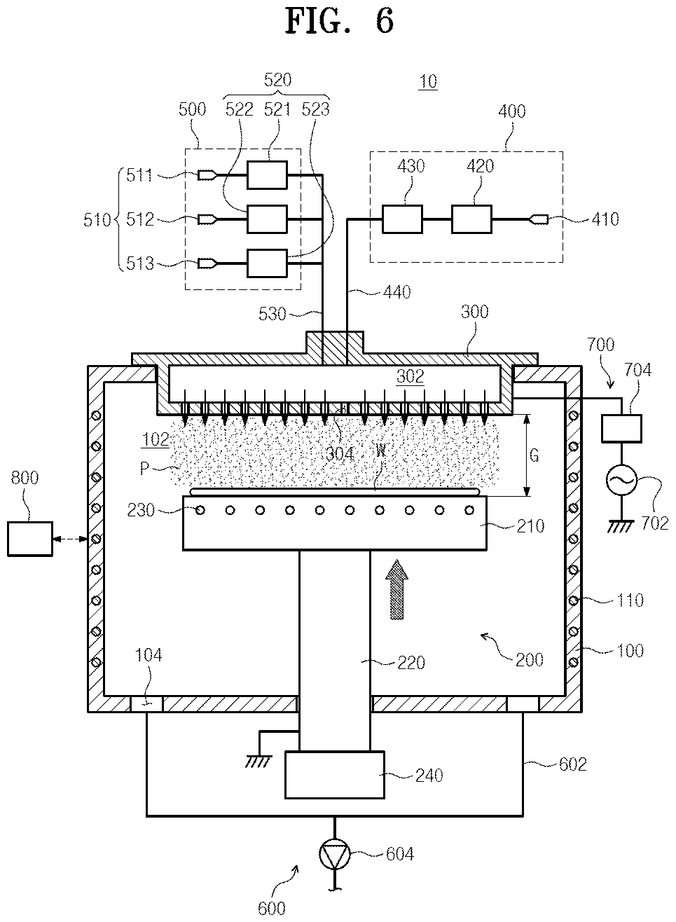

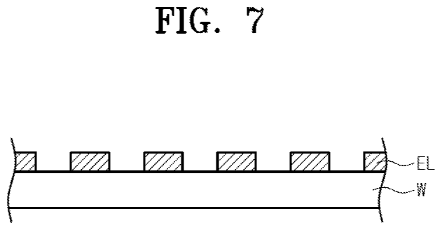

The film removal operation S12 may remove a film provided on the substrate W. The removal of the film may be performed by transferring plasma P generated from the process gas or treatment fluid to the film on the substrate W. For example, in the film removal operation S12, the hard mask ML provided on the substrate W may be removed. In the film removal operation S12, the gas supply unit 500 may supply hydrogen and inert gas (for example, argon) to the treating space 102. Additionally, in the film removal operation S12, the fluid supply unit 400 may supply water to the treating space 102. In addition, in the film removal operation S12, the gap G between the chuck 200 and the baffle 300 may be maintained as a first gap, and the pressure in the treating space 102 may be maintained as a first pressure, as illustrated in FIG. 6. The first gap may be a relatively small gap, and the first pressure may be a relatively high pressure. Upon completion of performing the film removal operation S12, a film provided on the substrate W, such as the hard mask ML, may be removed, as illustrated in FIG. 7.

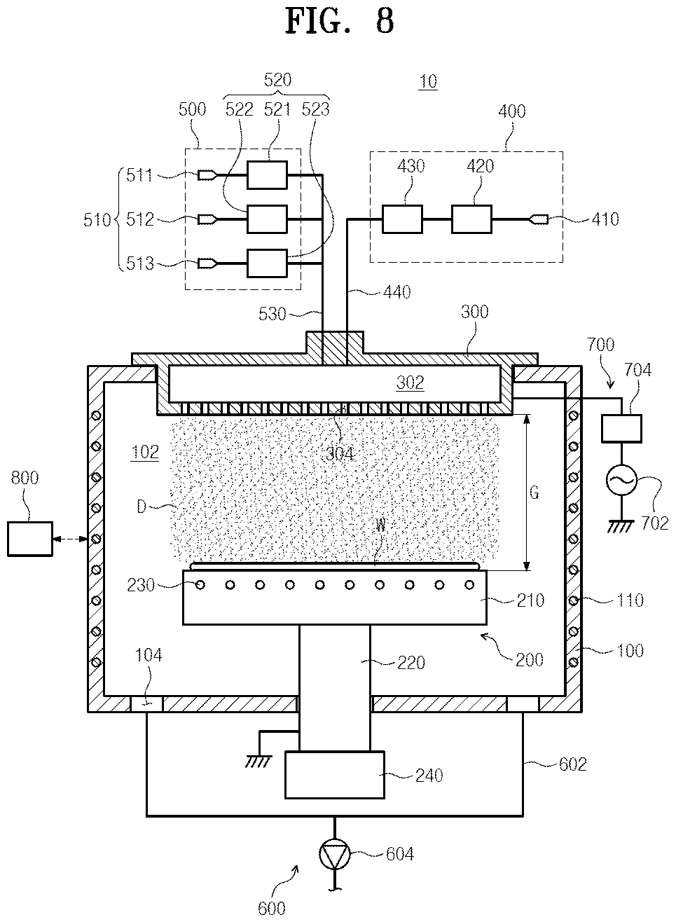

The protective film formation operation S13 may form a protective film on the substrate W. The protective film PL formed on the substrate W may be a protective film containing oxygen. For example, the protective layer PL may be passivation oxide. The protective layer PL may act as an insulator. The protective film PL may prevent the substrate W or the etched layer EL from being over-etched in a liquid treatment operation that may be performed at a later time. In the protective film formation operation S13, the gas supply unit 500 may supply inert gas (for example, argon) to the treating space 102. Also, in the protective film formation operation S13, the fluid supply unit 400 may supply water to the treating space. Further, in the protective film forming operation S13, the gap G between the chuck 200 and the baffle 300 may be maintained at a second gap larger than the first gap, and the pressure in the treating space 102 may be maintained at a second pressure smaller than the first pressure, as illustrated in FIG. 8. The second gap may be a relatively large gap, and the second pressure may be a relatively low pressure. Upon completion of performing the protective film formation operation S13, the protective film PL may be formed on the substrate W, as illustrated in FIG. 9.

In the substrate unloading operation S14, the substrate W may be unloaded through the loading opening of the chamber 100. The unloading of the substrate W may be performed by the hand of the transfer robot. At this time, the lift pin (not illustrated) provided on the chuck 200 may rise, the hand may enter the treating space 102, the substrate W may be loaded onto the hand, the lift pin may lower, and the hand may unload the substrate W from the treating space 102.

The substrate W unloaded from the treating space 102 may be transferred to the liquid processing chamber (not illustrated). The substrate W transferred to the liquid treatment chamber may be placed on a susceptor that may support and rotate the substrate W. The susceptor may rotate the substrate W, and a nozzle provided in the liquid treatment chamber may supply a chemical solution to the rotating substrate W. As described above, the substrate is treated by the chemical solution in the state where the protective film PL is formed on the substrate, which minimizes problems, such as over-etching by the chemical solution. In other words, the protective film PL may act as an insulator, protect a device from the next etching process, and contribute to efficient device dimensioning. Furthermore, since the above-described substrate processing apparatus 10 is capable of performing both the process of removing the film on the substrate W and the process of forming the protective film on the substrate W, it is not necessary to transfer the substrate W to a separate device for forming the protective film PL, and accordingly, the number of substrates W that can be processed per unit time may be increased, and the space occupied by the substrate processing facility including the substrate processing apparatus 10 may also be effectively reduced.

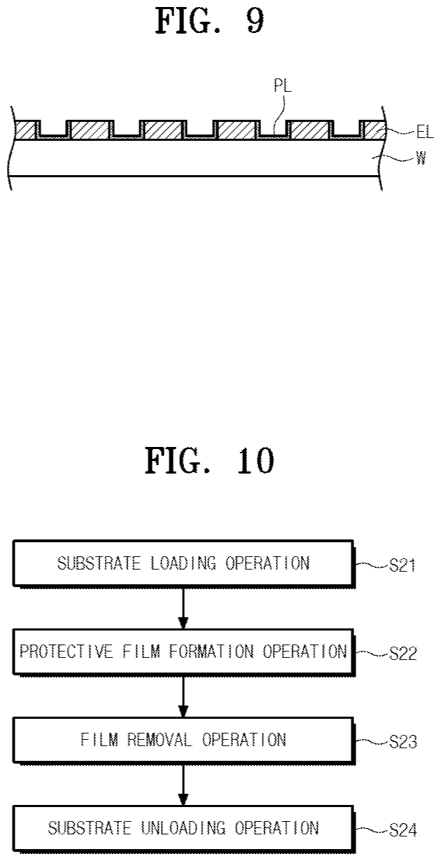

In the example described above, the protective film formation operation S13 is performed after the film removal operation S12, but the present invention is not limited to this. For example, as illustrated in FIG. 10, a substrate loading operation S21, a protective film formation operation S22, a film removal operation S23, and a substrate unloading operation S24 may be performed sequentially. In other words, the film removal operation S23 may be performed after the protective film formation operation S22.

The foregoing detailed description illustrates the present invention. Further, the above content illustrates and describes the exemplary embodiment of the present invention, and the present invention can be used in various other combinations, modifications, and environments. That is, the foregoing content may be modified or corrected within the scope of the concept of the invention disclosed in the present specification, the scope equivalent to that of the disclosure, and/or the scope of the skill or knowledge in the art. The foregoing exemplary embodiment describes the best state for implementing the technical spirit of the present invention, and various changes required in the specific application field and use of the present invention are possible. Accordingly, the detailed description of the invention above is not intended to limit the invention to the disclosed exemplary embodiment. Further, the accompanying claims should be construed to include other exemplary embodiments as well.

1. A method of processing a substrate, the method comprising:
a substrate loading operation of loading a substrate into a treating space of a chamber;
a film removal operation of removing a film provided on the substrate;
a protective film formation operation of forming a protective film containing oxygen on the substrate; and
a substrate unloading operation of unloading the substrate from the treating space.

2. The method of claim 1, wherein the protective film formation operation is performed after the film removal operation.

3. The method of claim 1, wherein the protective film formation operation is performed before the film removal operation.

4. The method of claim 1, further comprising:
a liquid treatment operation of supplying a chemical solution to the substrate and removing impurities remaining on the substrate or the protective film after the substrate unloading operation.

5. The method of claim 1, wherein the film removal operation is performed by transferring plasma to the film.

6. The method of claim 5, wherein in the film removal operation, a gap between a chuck supporting the substrate and a baffle disposed above the substrate is a first gap, and a pressure in the treating space is maintained at a first pressure,
in the protective film formation operation, a gap between the chuck and the baffle is a second gap greater than the first gap, and a pressure in the treating space is maintained at a second pressure less than the first pressure,
any one of the chuck and the baffle is connected with a power unit that generates an electric field in the treating space, and
the other of the chuck and the baffle is grounded.

7. The method of claim 5, wherein in the film removal operation, water, hydrogen, and inert gas are supplied to the treating space, and
in the protective film formation operation, water, hydrogen, and inert gas are supplied to the treating space.

8. An apparatus for processing a substrate, the apparatus comprising:
a chamber having a treating space;
a chuck for supporting a substrate in the treating space, and moving the substrate in upward and downward directions;
a gas supply unit for supplying process gas to the treating space;
a fluid supply unit for supplying a treatment fluid to the treating space;
a baffle disposed above the substrate supported on the chuck and formed with a spray hole through which the process gas and/or the treatment fluid flows;
an exhaust unit for exhausting the treating space;
a power unit for generating an electric field in the treating space; and
a controller,
wherein the controller controls at least one of the gas supply unit, the exhaust unit, the fluid supply unit, the chuck, and the power unit to remove a film provided on the substrate supported on the chuck, and to form a protective film containing oxygen on the substrate supported on the chuck.

9. The apparatus of claim 8, wherein the controller controls at least one of the gas supply unit, the exhaust unit, the fluid supply unit, the chuck, and the power unit to form the protective film, after the film is removed.

10. The apparatus of claim 8, wherein the controller controls at least one of the gas supply unit, the exhaust unit, the fluid supply unit, the chuck, and the power unit to form the protective film, before the film is removed.

11. The apparatus of claim 8, wherein the controller controls at least one of the chuck, the exhaust unit, the gas supply unit, and the fluid supply unit to maintain a gap between the chuck and the baffle at a first gap during removal of the film, and to maintain a pressure in the treating space at a first pressure, and
the controller controls at least one of the chuck, the exhaust unit, the gas supply unit, and the fluid supply unit to maintain a gap between the chuck and the baffle at a second gap greater than the first gap, and to maintain a pressure in the treating space at a second pressure less than the first pressure, during the formation of the protective film.
